(19) United States
(12) Patent Application Publication
(10) Pub. No.: US 2015/0069614 A1
(43) Pub. Date: Mar. 12, 2015

(54) SEMICONDUCTOR DEVICE AND MANUFACTURING METHOD THEREOF

(71) Applicant: KABUSHIKI KAISHA TOSHIBA, Tokyo (JP)

(72) Inventors: Yukie NISHIKAWA, Ishikawa (JP); Hironobu SHIBATA, Ishikawa (JP); Nobuhiro TAKAHASHI, Ishikawa (JP)

(73) Assignee: KABUSHIKI KAISHA TOSHIBA, Tokyo (JP)

(21) Appl. No.: 14/194,478

(22) Filed: Feb. 28, 2014

(30) Foreign Application Priority Data
Sep. 9, 2013 (JP) 2013-186709

(51) Int. Cl. H01L 29/45; H01L 29/739; H01L 29/861; H01L 21/283

(52) U.S. Cl. CPC H01L 29/456; H01L 21/283; H01L 29/7393; H01L 29/861
USPC 257/766; 438/659

(57) ABSTRACT

A semiconductor device includes a first metal layer disposed on a first surface of a semiconductor layer, or a portion thereof. The first metal layer is made of a first metal. At least a portion of the first metal layer is crystallized. A second metal layer is disposed on a second surface of the semiconductor layer. The second surface is opposite the first surface. The second metal layer is also made of the first metal and has at least a portion that is crystallized. In some embodiments, the first metal may be nickel. In some embodiments, the semiconductor device may be a power semiconductor device, such as an insulated gate bipolar transistor and a fast recovery diode.

### CROSS-REFERENCE TO RELATED APPLICATION

This application is based upon and claims the benefit of priority from Japanese Patent Application No. 2013-186709, filed Sep. 9, 2013 the entire contents of which are incorporated herein by reference.

### FIELD

Embodiments described herein relate generally to a semiconductor device and a manufacturing method thereof.

### BACKGROUND

A power device (semiconductor device) is used in a wide range of fields such as industrial machinery, electric power generation and control, and consumer electronics. Among such power devices, an insulated gate bipolar transistor (IGBT) is widely used when a withstand (breakdown) voltage of 600 V or higher is required. In an IGBT, a trade-off curve between a saturation voltage and a switching loss is used as an index indicating IGBT characteristics. A saturation voltage can be reduced by reducing the thickness of a silicon portion.

On the other hand, in an IGBT for use with a high current density, a technique of providing a nickel layer on front and back surfaces of a chip in order to cool the device through both the front and back surfaces has been disclosed. However, when a nickel layer is incorporated into a chip, the chip may become warped. A chip easily warps when the thickness of a silicon portion is reduced for reduction of a saturation voltage. When a warp amount becomes large, it is hard to assemble devices because soldering the warped chips becomes difficult. Thus, by attempting to enhance a chip property (e.g., a reduction in saturation voltage) by reducing the thickness of a silicon portion, it becomes more difficult to assemble devices by increasing a chip warp amount.

### DESCRIPTION OF THE DRAWINGS

FIG. 1 is a cross-sectional view illustrating a semiconductor device according to a first embodiment.

FIG. 2 is a flowchart illustrating a method of manufacturing a power semiconductor device according to the first embodiment.

FIGS. 3A and 3B are X-ray diffraction curves of nickel layers in which the horizontal axis represents a value of diffraction angle (2θ) and the vertical axis represents an intensity of an X-ray diffraction.

FIG. 4A is a diagram illustrating a semiconductor device according to an example embodiment.

FIG. 4B is a diagram illustrating a semiconductor device according to a comparative example.

FIG. 5 is a graph depicting an effect of the thickness of a nickel layer on the back side on the warp amount of a chip, in which the horizontal axis represents the thickness of the nickel layer on the back side and the vertical axis represents the warp amount of the chip.

FIG. 6A is a graph depicting an effect of the thickness of a silicon portion on the warp amount of a chip, in which the horizontal axis represents the thickness of the silicon portion and the vertical axis represents the warp amount of the chip.

FIG. 6B is a graph depicting a relationship between the thickness of the silicon portion and a warp suppressing effect obtained by increasing the thickness of the nickel layer on the back side, in which the horizontal axis represents the thickness of the silicon portion and the vertical axis represents decrease in a warp amount.

FIG. 7 is a cross-sectional view illustrating a semiconductor device according to a second embodiment.

### DETAILED DESCRIPTION

A semiconductor device of an embodiment includes a first metal layer disposed on a first surface of a semiconductor layer, or a portion thereof. The first metal layer comprises a first metal and at least a portion of the first metal layer is crystallized. A second metal layer is disposed on a second surface of the semiconductor layer. The second surface opposite the first surface, that is the first and second surfaces are on opposite sides of the semiconductor layer (e.g., front and back sides). The second metal layer also comprises the first metal and has at least a portion that is crystallized.

In general, according to one embodiment, there is provided a semiconductor device including: a semiconductor portion; a first metal layer that is provided on a top surface of the semiconductor portion and contains a first metal and of which at least a part is crystallized; and a second metal layer that is provided on a bottom surface of the semiconductor portion and contains the first metal and of which at least a part is crystallized.

According to another embodiment, there is provided a method of manufacturing a semiconductor device including: forming a first metal layer, which contains a first metal, on a top surface of a semiconductor portion; introducing dopants into a bottom surface of the semiconductor portion; performing a heat treatment to activate the dopants and to crystallize at least a part of the first metal layer; and forming a second metal layer, which contains the first metal, on the bottom surface of the semiconductor portion such that at least a part of the second metal layer is crystallized.

Hereinafter, exemplary embodiments will be described with reference to the drawings.

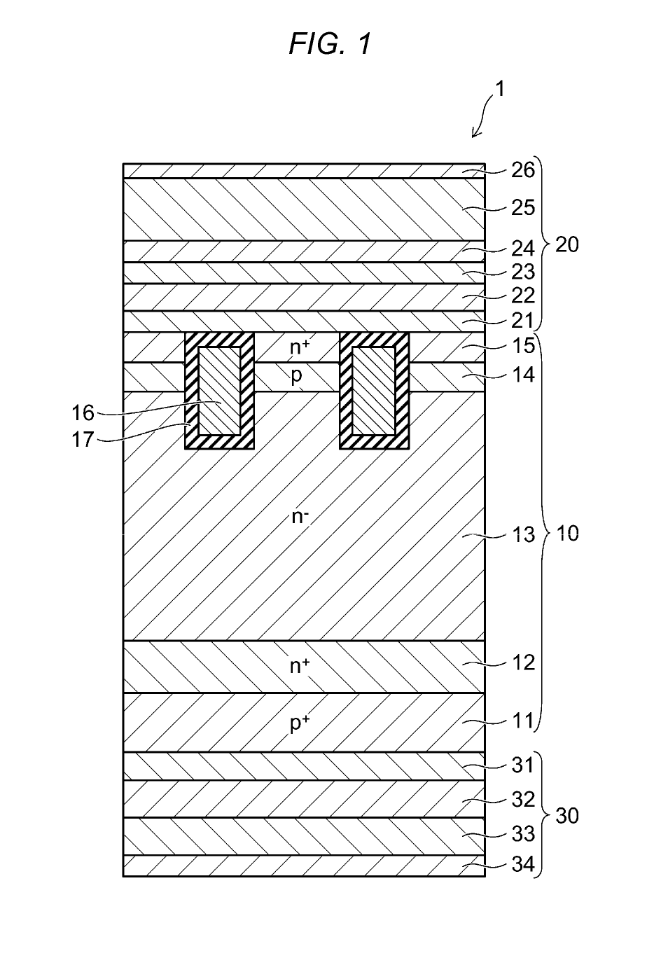

FIG. 1 is a cross-sectional view illustrating a semiconductor device according to a first embodiment.

As illustrated in FIG. 1, the semiconductor device 1 according to this first embodiment is an IGBT having a breakdown (withstand) voltage in a range of, for example, 600 V to 800 V. In addition, the external size of the semiconductor device 1 is a chip size having a length of one side of, for example, 10 mm (millimeter) to 15 mm.

In the semiconductor device 1 (hereinafter, also simply referred to as “device 1” or “chip 1”) of this example, a silicon portion 10 is provided as a semiconductor portion, a front electrode structure 20 is provided on a top surface of the silicon portion 10, and a back electrode structure 30 is provided on a bottom surface of the silicon portion 10. For example, a guard ring region (not specifically illustrated) including a field plate is provided around the chip as a termination region for improving a breakdown voltage.

In the silicon portion 10, a p⁺ type collector layer 11, an n⁺ type buffer layer 12, an n⁻ type bulk layer 13, a p type base layer 14, and an n⁺ type emitter layer 15 are stacked in sequence. In addition, a trench gate electrode 16 is provided so as to pass through the n⁺ type emitter layer 15 and the p type base layer 14 from a top surface of the silicon portion 10 and reach the inside of the n⁻ type bulk layer 13. The trench gate electrode 16 is a base electrode of the device 1. A gate insulating film 17 including, for example, silicon oxide is provided around the trench gate electrode 16. The silicon portion 10 is made of crystalline silicon (Si), and the thickness of the entire silicon portion 10 is, for example, 60 μm (micron) to 120 μm and is for example, 70 μm. The silicon portion 10 may be a single crystalline silicon.

The front electrode structure 20 comprises, in order from the silicon portion 10, a titanium (Ti) layer 21 having a thickness of, for example, 30 nm (nanometer), a titanium nitride (TiN) layer 22 having a thickness of, for example, 150 nm (nanometer), an aluminum (Al) layer 23, an aluminum-copper (AlCu) alloy layer 24, a nickel layer 25 having a thickness of, for example, 5 μm, and a gold (Au) layer 26 having a thickness of, for example, 50 nm. The total thickness of the aluminum layer 23 and the aluminum-copper alloy layer 24 is, for example, 4 μm. The nickel layer 25 is formed using an electroless plating method, and includes nickel and phosphorus resulting in a nickel-phosphorus (Ni—P) compound. In the nickel layer 25, a phosphorus content is, for example, 4 weight % to 10 weight %, and at least a portion of the nickel layer 25 is crystallized. In some embodiments, a large portion of the nickel layer 25 may be crystallized. The crystallized portion is not necessary to be placed uniformly. In the nickel layer, the crystallized portion can be localized, where a certain portion can be amorphous, the other portion can be strongly crystallized, and the other portion can be weakly crystallized. It is essential that the nickel layer contains at least a crystallized portion.

In this example, the front electrode structure 20 is configured to be an emitter electrode of the device 1. The nickel layer 25 and the gold layer 26 are electrode pads which are soldered during packaging of the device 1. In addition, the front electrode structure 20 may be provided with an interlayer dielectric film (not specifically illustrated).

In the back electrode structure 30 comprises, in order from the silicon portion 10, an aluminum-silicon (AlSi) alloy layer 31 having a thickness of, for example, 200 nm, a titanium layer 32 having a thickness of, for example, 200 nm, a nickel layer 33 having a thickness of, for example, 1 μm, and a gold-silver (AuAg) alloy layer 34 having a thickness of, for example, 100 nm. The nickel layer 33 is formed using a sputtering method and is composed of substantially pure nickel, and at least a part of the nickel layer 33 is crystallized. In some embodiments, a large part of the nickel layer 33 can be crystallized. The crystallized portion is not necessary to be placed uniformly. In the nickel layer, the crystallized portion can be localized, where a certain portion can be amorphous, the other portion can be strongly crystallized, and the other portion can be weakly crystallized. In the embodiments, the nickel layer contains at least a crystallized portion. In this example, the back electrode structure 30 is a collector electrode of the device 1.

It is desirable that the thickness of the nickel layer 33 of the back electrode structure 30 is greater than or equal to 15% of the thickness of the nickel layer 25 of the front electrode structure 20. In the above-described example, since the thickness of the nickel layer 25 is 5 μm and the thickness of the nickel layer 33 is 1 μm, the thickness of the nickel layer 33 is 20% of the thickness of the nickel layer 25.

Next, a method of manufacturing a semiconductor device will be described.

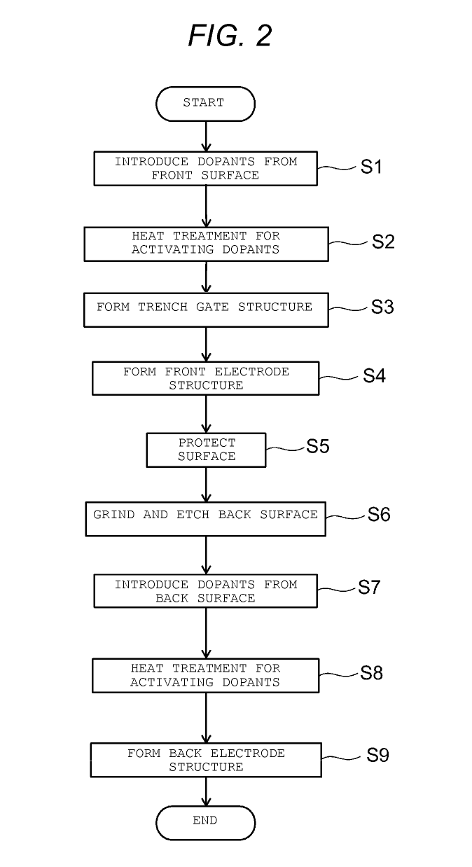

FIG. 2 is a flowchart illustrating the method of manufacturing a semiconductor device according to the first embodiment. Hereinafter, the description will be made with reference to FIGS. 1 and 2.

First, an n type silicon wafer is prepared as the silicon portion 10. Hereinafter, for convenience of description, this silicon wafer will be referred to as “silicon portion 10”. In an initial state, the silicon portion 10 has two major surfaces which may be referred to as “a front surface” and “a back surface.

As illustrated in Step S1, various dopants are introduced from the front surface using an ion implantation method. After the ion implantation, in Step S2, a heat treatment of the semiconductor layer is performed to activate the dopants. As a result, the p type base layer 14 and the n⁺ type emitter layer 15 are formed inside the silicon portion 10.

Next, as illustrated in Step S3, a trench structure is formed by a reactive ion etching method, the gate insulating film 17 is formed on the inside of the trench, and the trench gate electrode 16 is embedded into the trench. As a result, a trench gate structure is formed.

The other steps, including the ion implantation, the heat treatment, a wet etching process, a dry etching process, an insulating film formation, a conductive film formation and so on, are repeatedly performed to make a desired structure in the silicon portion 10 or on the silicon portion 10.

Next, as illustrated in Step S4, the front electrode structure 20 on the front surface is formed on the silicon portion 10.

Specifically in this example, using a sputtering method, the titanium layer 21 having a thickness of, for example, 30 nm is formed, the titanium nitride layer 22 having a thickness of, for example, 150 nm is formed, and the aluminum layer 23 and the aluminum-copper alloy layer 24 having a total thickness of, for example, 4 μm are formed.

Next, the nickel layer 25 having a thickness of, for example, 5 μm is formed by an electroless plating method using a plating solution containing phosphorus. Next, the gold layer 26 having a thickness, for example, 50 nm is formed by the electroless plating method. At this time, the nickel layer 25 is substantially amorphous.

Next, as illustrated in Step S5, a protective tape (not specifically illustrated) is attached onto a top surface of the front electrode structure 20 to protect the top surface thereof.

Next, as illustrated in Step S6, a back surface of the silicon portion 10 is ground and polished to decrease the thickness thereof to a predetermined value. Next, a portion of silicon portion 10 that may have been damaged by the grinding-and-polishing process is removed by wet etching. At this time, the thickness of the silicon portion 10 is, for example, 60 μm to 120 μm and is for example, 70 μm. Next, the protective tape can be peeled off at the end of this step, or can be peeled off after the other step.

Next, as illustrated in Step S7, various dopants are introduced from the back surface of the silicon portion 10 using an ion implantation method. As a result, the n⁺ type buffer layer 12 and the p⁺type collector layer 11 are formed inside the silicon portion 10.

Next, as illustrated in Step S8, a heat treatment is performed to activate dopants that have been introduced into the silicon portion 10. Before this heat treatment, the nickel layer is substantially amorphous. Due to this heat treatment, at least a part of the nickel layer 25 is crystallized. For example, a laser annealing method can be used as the heat treatment. A part of laser energy is carried by the silicon portion 10 and reach the nickel layer 25. At this time, because the nickel layer 25 shrinks and the volume thereof is decreased, the nickel layer 25 applies a shrinking force to the top surface of the silicon portion 10. This shrinking force acts such that the silicon wafer is warped to be downwardly convex.

Next, as illustrated in Step S9, the back electrode structure 30 is formed on the back surface of the silicon portion 10.

Specifically in this example, by using a sputtering method, the aluminum-silicon alloy layer 31 having a thickness of, for example, 200 nm is formed, the titanium layer 32 having a thickness of, for example, 200 nm is formed, the nickel layer 33 having a thickness of, for example, 1 μm is formed, and the gold-silver alloy layer 34 having a thickness of, for example, 100 nm is formed.

Because the nickel layer 33 is formed using a sputtering method, at least a part (or a large part) of the nickel layer 33 is crystallized during the film formation.

When nickel is deposited on the titanium layer 32 and a part of it is crystallized, the deposited nickel shrinks in volume upon crystallization. Therefore, the nickel layer 33 applies a shrinking force to the back surface of the silicon portion 10. This shrinking force acts such that the silicon wafer is warped to be upwardly convex.

In subsequent steps, the silicon wafer (silicon portion 10) with the front electrode structure 20 and the back electrode structure 30 can be divided into plural chips by dicing. As a result, the semiconductor device 1 according to this first embodiment is manufactured.

Next, the effects of this first embodiment will be described.

In a semiconductor device 1, the thickness of the silicon portion 10 is, for example, 60 μm to 120 μm and is assumed as, for this specific example to be 70 μm. Since this thickness is relatively small for an IGBT having a breakdown voltage in a range of 600 V to 800 V, the balance between a saturation voltage and a switching loss is generally improved. For example, when the thickness of the silicon portion 10 is 80 μm, a saturation voltage is 2.0 V. However, when the thickness of the silicon portion 10 is 70 μm, a saturation voltage is decreased to 1.75 V. In this way, in an IGBT having a breakdown voltage in a range of 600 V to 800 V, a saturation voltage can be improved by 10% to 20% by reducing the thickness of the silicon portion 10 from 80 μm to 70 μm.

In addition, in the device 1, the nickel layer 25 is formed above the silicon portion 10, and electrode pads which are soldered during assembly are formed. The nickel layer 33 containing the same metal of nickel as that of the nickel layer 25 is formed below the silicon portion 10. At least a part of each of the nickel layers 25 and 33 is crystallized. Therefore, the nickel layer 25 applies a shrinking force to the top surface of the silicon portion 10, and the nickel layer 33 applies a shrinking force to the bottom surface of the silicon portion 10. As a result, the shrinking force of the nickel layer 25 to warp the chip may be counteracted by the shrinking force of the nickel layer 33, thereby suppressing the wrap amount of the chip. For example, in this example embodiment, when the length of one side of the chip is 10 mm, the warp amount of the chip is 80 μm. Typically, when a warp amount of the chip is less than or equal to 100 μm, assembly defects are not caused by chip warping, and a high yield of assembly can be obtained.

In addition, since at least a part of the nickel layers 25 and 33 is already crystallized, the crystallized portion of the nickel layers 25 and 33 are almost unchanged in subsequent soldering processes during assembly/packaging, and the warp amount of the chip is almost unchanged by the additional crystallization during soldering steps, or other subsequent steps. In this way, in the device 1, the warp amount is small, and almost unchanged in the assembly process such as the soldering process. Therefore, an assembly process of the chip can be improved.

Accordingly, in the device 1, even if the thickness of the silicon portion 10 is reduced to improve a trade-off between a saturation voltage and a switching loss, the warp amount of the chip may still be suppressed. That is, both chip characteristics and an assembly process can be simultaneously improved.

Furthermore, in this first embodiment, after the nickel layer 25 is formed using an electroless plating method in Step S4 of FIG. 2, the heat treatment for activating the dopants is performed in Step S8. Therefore, a microstructure of the nickel layer 25 is substantially amorphous after the plating, but is crystallized by the heat treatment. In addition, in Step S9, the nickel layer 33 is formed using a sputtering method. Therefore, at least a part of the nickel layer 33 is crystallized after the film formation. In this way, according to this embodiment, the nickel layers 25 and 33 can be crystallized without performing a special crystallization treatment.

On the other hand, when the nickel layer 33 is formed using an electroless plating method and then a heat treatment is not performed thereon, the nickel layer 33 is substantially amorphous. In this case, the nickel layer 33 cannot generate a large shrinking force to act against the shrinking force of the nickel layer 25, and the chip is warped to be downwardly convex. Therefore, for example, solder wettability deteriorates in the subsequent soldering process, and thus an assembly process deteriorates.

Whether the microstructure of the nickel layer is crystalline or amorphous can be determined by a 0-2θ method using X-ray diffraction (XRD).

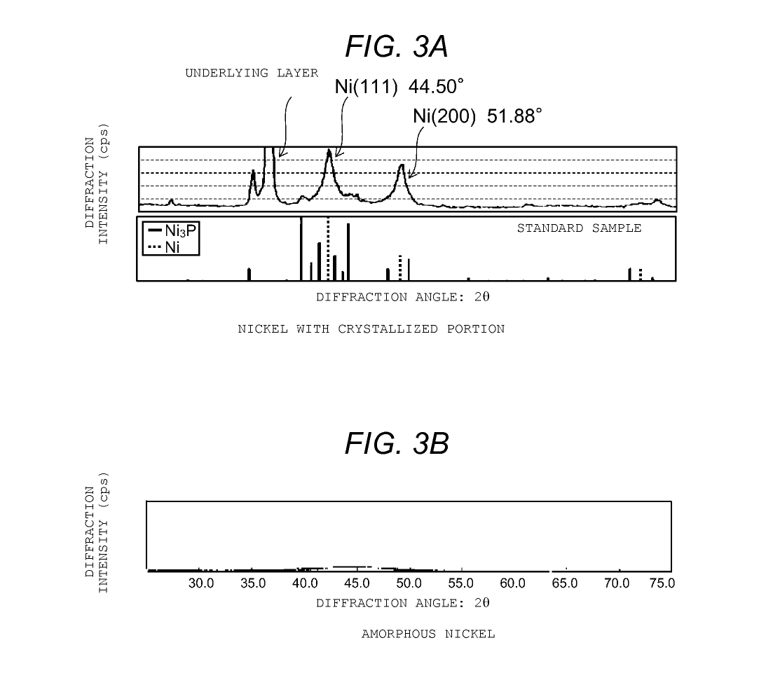

FIGS. 3A and 3B are diagrams illustrating X-ray analysis results of a nickel layer in which the horizontal axis represents a value of diffraction angle (2θ) and the vertical axis represents a diffraction intensity of an X-ray.

As illustrated in FIG. 3A, when a nickel layer contains a crystallized portion, a peak of 2θ=44.45° indicating the (111) plane of nickel (Ni); and a peak of 2θ=51.88° indicating the (200) plane of nickel (Ni) are observed. The peak intensity becomes stronger with increasing the crystallized portion in the nickel layer.

On the other hand, as illustrated in FIG. 3B, when a nickel layer is amorphous, an extremely broad peak having a weak intensity is observed around 2θ=40° to 50°, but a sharp peak indicating crystallinity is not observed.

Further, in this embodiment, the thickness of the nickel layer 33 on the back side is greater than or equal to 15% of the thickness of the nickel layer 25 on the front side. As a result, the warp amount of the chip may be more reliably suppressed. Hereinafter, this effect will be described using a test example.

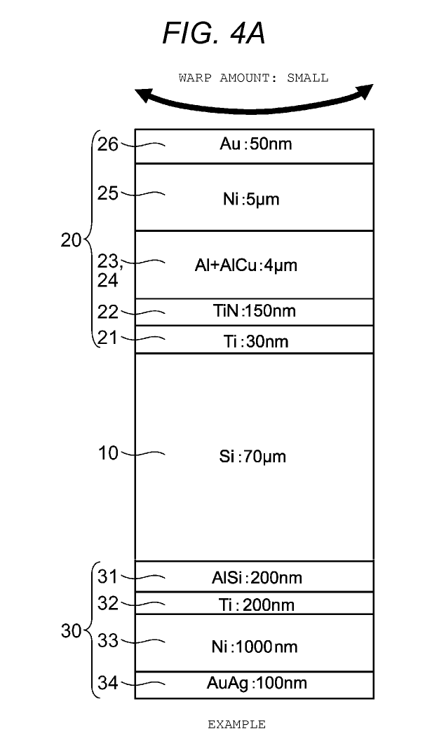

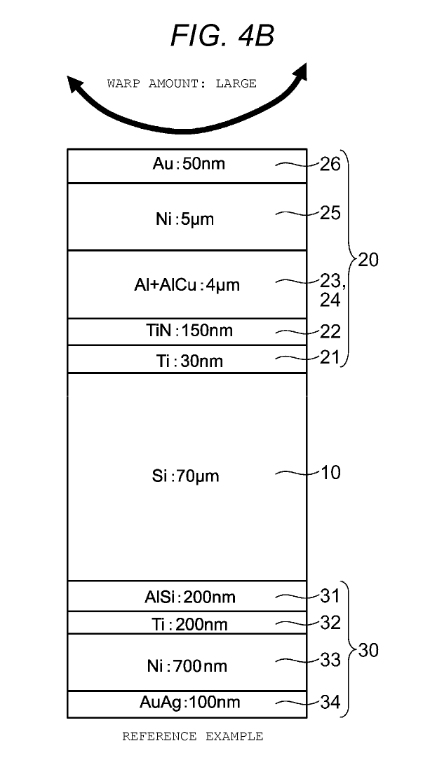

FIG. 4A is a diagram illustrating a semiconductor device according to an example, and FIG. 4B is a diagram illustrating a semiconductor device according to a reference example.

As illustrated in FIG. 4A, the configuration of the device according to the example is the same as that of the device 1 illustrated in FIG. 1, and the thickness of the nickel layer 33 is 1 μm. In addition, as illustrated in FIG. 4B, the configuration of the device according to the reference example is different from that of the device 1 illustrated in FIG. 4A, in that the thickness of the nickel layer 33 is 700 nm. In this test example, samples illustrated in FIGS. 4A and 4B; and samples obtained by changing the thickness of each portion of the samples illustrated in FIGS. 4A and 4B were prepared, and the warp amount of each sample was measured.

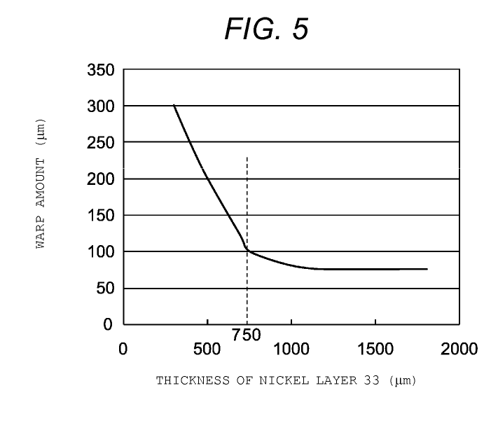

FIG. 5 is a graph illustrating an effect of the thickness of a nickel layer (e.g., nickel layer 33) on the back side on the warp amount of the chip, in which the horizontal axis represents the thickness of the nickel layer on the back side and the vertical axis represents the warp amount of the chip.

As illustrated in FIG. 5, when the thickness of the silicon portion 10 was the same and the thickness of the nickel layer 33 on the back side was decreased, the warp amount of the chip was increased. In particular, when the thickness of nickel layer 33 was less than 750 nm, the warp amount of the chip was rapidly increased.

In the example illustrated in FIG. 5, the thickness of the nickel layer 25 on the front side was 5 μm. As illustrated in FIG. 5, when the thickness of the nickel layer 33 on the back side was greater than or equal to 15% of the thickness of the nickel layer 25 on the front side, for example, was greater than or equal to 750 nm, it is found that the warp amount of the chip was as small as less than or equal to 100 μm. As a result, an assembly process was improved. On the other hand, when the thickness of the nickel layer 33 was 700 nm, the warp amount of the chip was 120 μm. As a result, an assembly process was deteriorated.

On the other hand, when the thickness of the nickel layer 33 was greater than or equal to 1 μm, the chip warping suppressing effect was saturated—that is, chip warping was not significantly improved for thicknesses of nickel layer 33 greater than or equal to 1 μm. In addition, when the thickness of the nickel layer 33 was excessively great, nickel burrs were formed during dicing, and there were some cases where defects occurred on the chips as a result of the excess nickel layer thicknesses. Therefore, it is preferable that the thickness of the nickel layer 33 generally be less than or equal to 1.5 μm. But, even if the thickness of the nickel layer 33 is greater than or equal to 1.5 μm, the formation of burrs can be prevented by removing the nickel layer 33 from a dicing line area before dicing—although this increases the number of overall process steps in the manufacturing of the device 1.

Based on the above results, it is preferable that the thickness of the nickel layer 33 on the back side be greater than or equal to 15% of the thickness of the nickel layer 25 on the front side and generally less than or equal to 1.5 μm overall.

Alternatively, if the thickness of the nickel layer 33 on the back side is fixed and the thickness of the nickel layer 25 on the front side is varied, the same effect can be obtained as the warp amount of the chip also depends on the thickness of the nickel layer 25 on the front side.

As described above, when the thickness of the nickel layer 25 was 5 μm, the warp amount of the chip was approximately 80 μm. When the thickness of the nickel layer 25 was 6 μm, the warp amount was increased to approximately 100 μm. On the other hand, when the thickness of the nickel layer 25 was 4 μm, the warp amount was decreased to approximately 60 μm. In this way, even when the thicknesses of the nickel layers 33 on the back side of various chips are the same, the warp amount of the chip 1 can be reduced by reducing the thickness of nickel layer 25.

For packaging using the device 1, the nickel layer 25 is generally soldered, but nickel is usually consumed by an alloying reaction with a solder. Therefore, if the nickel layer 25 is excessively thin, a solder reaches the aluminum-copper alloy layer 24 and the aluminum layer 23. As a result, the reliability of the device 1 deteriorates. Therefore, in order to secure sufficient reliability, the thickness of the nickel layer 25 is preferably greater than or equal to 4 μm and more preferably greater than or equal to 5 μm.

In addition, since the nickel layer 25 is formed by an electroless plating method using a plating solution containing phosphorus, the nickel layer 25 contains approximately several percentages of phosphorus. On the other hand, since the nickel layer 33 is formed by a sputtering method, the purity of nickel is high. The shrinking force of the nickel layer 33 having a high purity of nickel is generally greater than that of the nickel layer 25 having a lower purity of nickel. Therefore, even if the nickel layer 33 is thinner than the nickel layer 25, the nickel layer 33 can act against the shrinking force of the overall thicker nickel layer 25.

Further, in this example embodiment, the thickness of the silicon portion 10 is 60 μm to 120 μm. As a result, by controlling a ratio of the thicknesses of the nickel layers 25 and 33, the chip warping suppressing effect can be significantly large.

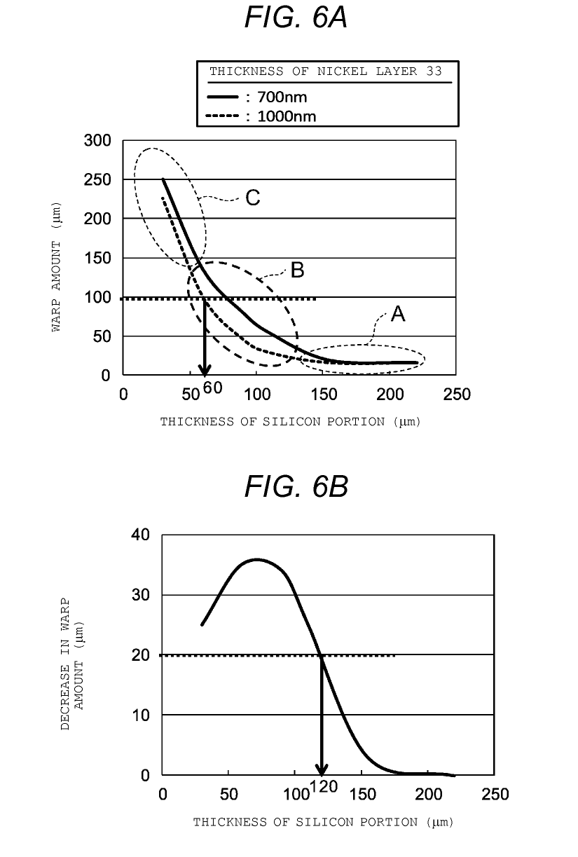

FIG. 6A is a graph illustrating an effect of the thickness of a silicon portion 10 on the warp amount of a chip, in which the horizontal axis represents the thickness of the silicon portion 10 and the vertical axis represents the warp amount of the chip, and FIG. 6B is a graph illustrating a relationship between the thickness of the silicon portion 10 and a warping suppressing effect obtained by increasing the thickness of the nickel layer 33 on the back side, in which the horizontal axis represents the thickness of the silicon portion 10 and the vertical axis represents a decrease value in warp amount. “Decrease value in warp amount” is obtained from FIG. 6A, and is a value obtained by subtracting the warp amount of the chip in which the thickness of the nickel layer 33 is 700 nm from the warp amount of the chip in which the thickness of the nickel layer 33 is 1 μm.

As illustrated in FIGS. 6A and 6B, in a region A, the silicon portion 10 is thick, and the warp amount of the chip is already small. Therefore, the chip warping suppressing effect obtained by increasing the thickness of the nickel layer 33 on the back side is relatively small.

In a region B, the silicon portion 10 is thinner than that of the region A, and the warping of the chip occurs more readily. Therefore, the chip warping suppressing effect obtained by increasing the thickness of the nickel layer 33 on the back side is relatively large.

In a region C, the silicon portion is thinner, and the warping of the chip is extremely large. Therefore, the chip warping suppressing effect obtained by increasing the thickness of the nickel layer 33 on the back side is relatively small. Based on the above-described results, it is found that the chip warping suppressing effect obtained by increasing the thickness of the nickel layer 33 on the back side is relatively large in the region B.

As illustrated in FIG. 6A, when the thickness of the silicon portion 10 is greater than or equal to 60 μm, the warp amount of the chip can be controlled to be less than or equal to 100 μm, thereby reliably realizing an improved assembly process. On the other hand, as illustrated in FIG. 6B, when the thickness of the silicon portion 10 is less than or equal to 120 μm, the chip warping suppressing effect obtained by increasing the thickness of the nickel layer 33 on the back side is relatively large. Accordingly, when the thickness of the silicon portion is 60 μm to 120 μm, the effect of this embodiment is relatively large.

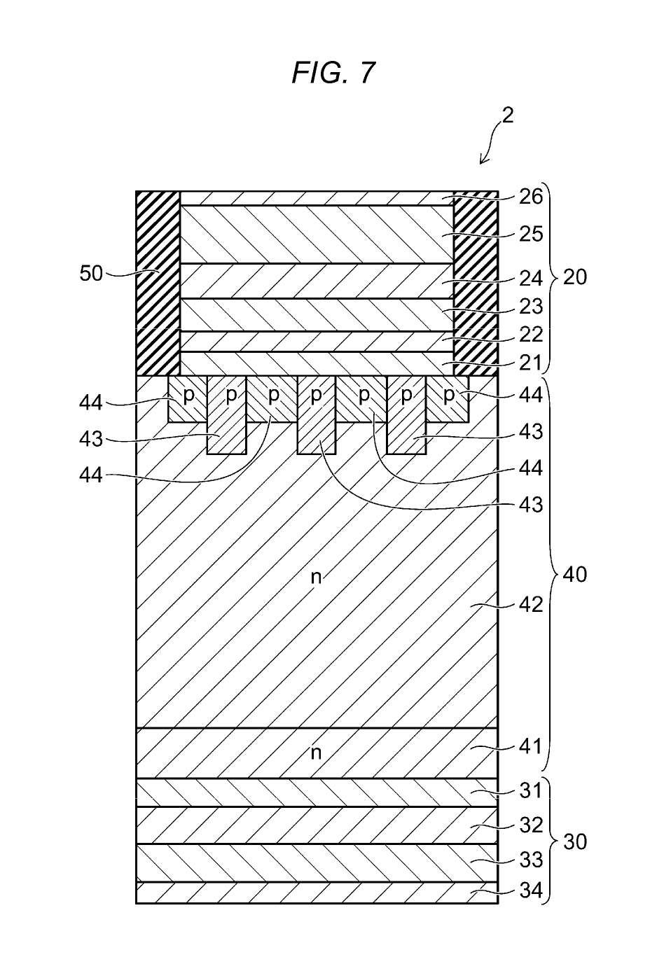

FIG. 7 is a cross-sectional view illustrating a semiconductor device according to a second embodiment.

As illustrated in FIG. 7, a semiconductor device 2 according to this second embodiment is a fast recovery diode (FRD).

In the device 2, a silicon portion 40 is provided as a semiconductor portion, the front electrode structure 20 is provided above the silicon portion 40, and the back electrode structure 30 is provided below the silicon portion 40. An insulating film 50 is provided around the front electrode structure 20. The layer structures of the front electrode structure 20 and the back electrode structure 30 are the same as those of the first embodiment.

The silicon portion 40 includes a high-concentration n type cathode layer 41 having a relatively high donor concentration and a low-concentration n type layer 42 having a relatively low donor concentration. Layer 41 and layer 42 disposed on each other. In addition, in a top surface of the low-concentration n type layer 42, high-concentration p type anode layers 43 having a relatively high acceptor concentration and low-concentration p type anode layers 44 having a relatively low acceptor concentration are alternately arranged along a direction parallel to the top surface.

In this embodiment, similarly to the first embodiment, the warping of the chip can be suppressed by crystallizing at least a part of the nickel layer 25 on the front side and at least a part of the nickel layer 33 on the back side. In addition, this effect can be more reliably obtained by controlling the thickness of the nickel layer 33 to be greater than or equal to 15% of the thickness of the nickel layer 25. The configuration, manufacturing method, operation, and effects of this second embodiment, other than the above-described features, are similar to those of the first embodiment.

In the above-described exemplary embodiments, the example in which the nickel layer is provided on both the front electrode structure 20 and the back electrode structure 30 is described. However, the metal layer to be provided on both the front and back sides is not limited to the nickel layer. For example, even when another metal layer such as an aluminum layer or a copper layer is provided, the above-described effect can also be obtained. If an aluminum layer is provided on the front electrode structure 20 instead of the nickel layer 25, a pure aluminum layer may be provided on the back electrode structure 30 instead of the nickel layer 33. However, an aluminum-silicon (AlSi) alloy layer or an aluminum-copper (AlCu) alloy layer may be provided on the back electrode structure 30. This is because the hardness of AlSi and AlCu which are alloys is higher than that of a high-purity aluminum, and thus AlSi and AlCu can act against the shrinking force of the aluminum layer on the front side.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a first metal layer disposed on a first surface of a semiconductor layer, the first metal layer comprising a first metal and having at least a portion that is crystallized; and
a second metal layer disposed on a second surface of the semiconductor layer, the second surface opposite the first surface, and the second metal layer comprising the first metal and having at least a portion that is crystallized.

2. The device according to claim 1, wherein the first metal is nickel.

3. The device according to claim 2, wherein the first metal layer includes 4 weight % to 10 weight % of phosphorous.

4. The device according to claim 3, wherein a thickness of the second metal layer is greater than or equal to 15% of a thickness of the first metal layer.

5. The device according to claim 4, wherein the semiconductor layer comprises silicon, and
a thickness of the semiconductor layer is 60 μm to 120 μm.

6. The device according to claim 3, wherein the semiconductor layer comprises silicon, and
a thickness of the semiconductor layer is 60 μm to 120 μm.

7. The device according to claim 2, wherein a thickness of the second metal layer is greater than or equal to 15% of a thickness of the first metal layer.

8. The device according to claim 2, wherein the semiconductor layer comprises silicon, and
a thickness of the semiconductor layer is 60 μm to 120 μm.

9. The device according to claim 1, wherein a thickness of the second metal layer is greater than or equal to 15% of a thickness of the first metal layer.

10. The device according to claim 9, wherein the semiconductor layer comprises silicon, and
a thickness of the semiconductor layer is 60 μm to 120 μm.

11. The device according to claim 1, wherein the semiconductor layer comprises silicon, and
a thickness of the semiconductor layer is 60 μm to 120 μm.

12. The device according claim 1, wherein the device has a breakdown voltage that is between 600 V to 800 V.

13. The device according to claim 1, wherein the device is an insulated gate bipolar transistor.

14. The device according to claim 1, wherein the device is a fast recovery diode.

15. A method of manufacturing a semiconductor device, comprising:
forming a first metal layer on a first surface of a semiconductor layer, the first metal layer comprising a first metal;
introducing dopants into the semiconductor layer from a second surface of the semiconductor layer that opposite the first surface;
performing a heat treatment to activate the dopants and to crystallize at least a portion of the first metal layer; and
forming a second metal layer on the second surface of the semiconductor layer, the second metal layer comprising the first metal and having at least a portion that is crystallized.

16. The method according to claim 15, wherein the first metal is nickel and,
a thickness of the second metal layer is greater than or equal to 15% of a thickness of the first metal layer.

17. The method according to claim 16, wherein the semiconductor layer comprises silicon, and
a thickness of the semiconductor layer is 60 μm to 120 μm.

18. The method according to claim 17, wherein the first metal layer is formed using an electroless plating method, and the second metal layer is formed using a sputtering method.

19. A method of manufacturing a semiconductor device, comprising:
introducing dopants into a semiconductor layer from a first surface of the semiconductor layer;
performing a heat treatment of the semiconductor layer to activate the dopants introducing into the semiconductor layer from the first surface of the semiconductor layer;
forming a trench gate structure in the semiconductor layer on the first surface of the semiconductor layer;
forming a first electrode structure on the first surface of the semiconductor layer;
protecting the first surface of the semiconductor layer;
thinning the semiconductor layer to a predetermined thickness by grinding a second surface of the semiconductor layer, the second surface opposite the first surface;
introducing dopants into the semiconductor layer from the second surface of the semiconductor layer;
performing a heat treatment of the semiconductor layer to activate the dopants introducing into the semiconductor layer from the second surface of the semiconductor layer; and
forming a second electrode structure on the second surface of the semiconductor layer, wherein
the first electrode structure includes a first metal layer comprising a first metal and has at least a portion that is crystallized during the heat treatment of the semiconductor layer to activate the dopants introducing into the semiconductor layer from the second surface of the semiconductor layer,
the second electrode structure includes a second metal layer comprising the first metal and has at least a portion that is crystallized.

20. The method according to claim 19, wherein the first metal is nickel,
a thickness of the second metal layer is greater than or equal to 15% of a thickness of the first metal layer,
the semiconductor layer comprises silicon, and
a thickness of the semiconductor layer is 60 μm to 120 μm.
